(19) United States
(12) Patent Application Publication
(10) Pub. No.: US 2025/0144768 A1
(43) Pub. Date: May 8, 2025

(54) BRUSH AGING PAD, CHEMICAL MECHANICAL POLISHING CLEANING APPARATUS, AND BRUSH AGING METHOD

(71) Applicant: SAMSUNG ELECTRONICS CO., LTD., Suwon-si (KR)

(72) Inventors: Heesung KIM, Suwon-si (KR); Kangin KIM, Suwon-si (KR); Dongwoo LEE, Suwon-si (KR)

(73) Assignee: SAMSUNG ELECTRONICS CO., LTD., Suwon-si (KR)

(21) Appl. No.: 18/910,425

(22) Filed: Oct. 9, 2024

(30) Foreign Application Priority Data
Nov. 3, 2023 (KR) 10-2023-0151151
Mar. 5, 2024 (KR) 10-2024-0031135

(51) Int. Cl. B24B 37/34; B24B 53/007; B24B 57/02

(52) U.S. Cl. CPC B24B 37/34; B24B 53/007; B24B 57/02

(57) ABSTRACT

Provided is a brush aging pad configured to age a surface protrusion of a brush configured to clean a semiconductor wafer in a chemical mechanical polishing cleaning apparatus, the brush aging pad including a pad body, wherein a roughness of at least one surface of the pad body ranges from 1 μm to 5 μm.

### CROSS-REFERENCE TO RELATED APPLICATION

This application claims priority to Korean Patent Application Nos. 10-2023-0151151 and 10-2024-0031135 filed on Nov. 3, 2023 and Mar. 5, 2024 in the Korean Intellectual Property Office, the disclosures of which are incorporated herein by reference in their entireties.

### BACKGROUND

### 1. Field

One or more embodiments of the present disclosure relate to a chemical mechanical polishing (CMP) cleaning apparatus including a brush aging pad, and a brush aging method.

### 2. Description of Related Art

As a semiconductor wafer manufacturing process, chemical mechanical polishing (CMP) has been introduced and used in a process of planarizing deposited layers of a semiconductor wafer and patterning the deposited layers using planarization. A CMP process may be a process of planarizing a wafer by causing a chemical reaction with the wafer using, for example, a slurry, a chemical liquid, and a polishing pad and simultaneously transmitting mechanical force to the wafer.

After the CMP process is performed, a cleaning process may be performed to remove particles and oxidation residues remaining on a wafer surface. A substrate cleaning apparatus for performing a cleaning process may use a brush that is slidably in contact with opposite surfaces of a wafer to clean the wafer.

In general, when a wafer is cleaned using a brush, the brush may be reversely contaminated by particles from the wafer. To resolve such an issue, intensive research has been conducted to scrub a surface protrusion of the brush to remove an external film of the surface protrusion such that deionized water (DIW), flowing into the brush, flows out toward the protrusion as much as possible.

Such a scrubbing process has been improved in terms of a brush being reversely contaminated by particles. However, due to a lack of mechanical cleaning power, there may be an issue such as severe particle contamination in an initial stage when a wafer is cleaned immediately after a brush is replaced.

### SUMMARY

One or more embodiments provide a brush aging pad capable of aging a brush to reduce contamination of wafer particles when a wafer is cleaned immediately after brush replacement.

One or more embodiments also provide a chemical mechanical polishing apparatus facilitating replacement of a brush aging pad and a wafer.

One or more embodiments also provide a brush aging method capable of aging a surface protrusion of a brush using a brush aging pad in a brush aging chamber to obtain an appropriate surface protrusion of the brush.

According to an aspect of one or more embodiments, there is provided a brush aging pad configured to age a surface protrusion of a brush configured to clean a semiconductor wafer in a chemical mechanical polishing cleaning apparatus, the brush aging pad including a pad body, wherein a roughness of at least one surface of the pad body ranges from 1 μm to 5 μm.

According to another aspect of one or more embodiments, there is provided a chemical mechanical polishing apparatus including a brush aging chamber configured to accommodate a pair of brushes, and a brush aging pad between the pair of brushes included in the brush aging chamber, the brush aging pad configured to age a surface protrusion of the brush, wherein the brush aging pad includes a pad body, a roughness of at least one surface the pad body ranging from 1 μm to 5 μm.

According to another aspect of one or more embodiments, there is provided a chemical mechanical polishing apparatus including a brush aging chamber configured to accommodate a brush; and a brush aging pad configured to be in contact with and to be pressed against a surface protrusion of the brush included in the brush aging chamber, wherein the brush aging pad comprises a pad body having circular shape, a surface roughness of at least one surface of the pad body ranging from 1 μm to 5 μm.

According to still another aspect of one or more embodiments, there is provided a brush aging method for aging a surface protrusion of a brush, the brush aging method including providing, into a brush aging chamber, a brush aging pad including a pad body having at least one surface having a roughness of 1 μm to 5 μm, providing the brush aging pad in a gap between a pair of brushes, pressing the pair of brushes against the brush aging pad, and rotating the brush aging pad.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic diagram of a chemical mechanical polishing apparatus for a semiconductor wafer according to one or more embodiments;

FIG. 2 is a schematic diagram of a structure of a wafer surface cleaning apparatus of the chemical mechanical polishing apparatus of FIG. 1;

FIG. 3 is a schematic perspective view of a brush and an aging pad according to one or more embodiments;

FIG. 4 is a schematic side view in a direction of the arrow of FIG. 3;

FIG. 5 is a schematic cross-sectional view of a brush taken along line A-A′ of FIG. 3;

FIG. 6 is a schematic cross-sectional view of a brush taken along line B-B′ of FIG. 5;

FIG. 7 is a schematic perspective view of aging of a brush using an aging pad according to one or more embodiments;

FIG. 8 is a schematic perspective view of aging of a brush using an aging pad according to one or more other embodiments;

FIG. 9 is a schematic perspective view of aging of a brush using an aging pad according to one or more other embodiments;

FIG. 10 is a flowchart of a brush aging method according to one or more embodiments; and

FIG. 11 is data of results of comparing particle contamination of wafer cleaning after brush aging is performed using a brush aging method according to one or more embodiments with particle contamination according to the related art.

### DETAILED DESCRIPTION

Hereinafter, preferred example embodiments will be described with reference to the attached drawings.

Example embodiments may be modified into many different forms, and may be provided for a more complete description of the present disclosure to those skilled in the art. Accordingly, the shapes and sizes of the components in the drawings may be exaggerated for clarity of description, and components denoted by the same reference numerals in the drawings may be the same components.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.”

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

The terms used herein describe particular example embodiments only, and the present disclosure is not limited thereby. As used herein, singular forms “a,” “an,” and “the” are intended to include the plural forms as well, unless the context clearly indicates otherwise.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

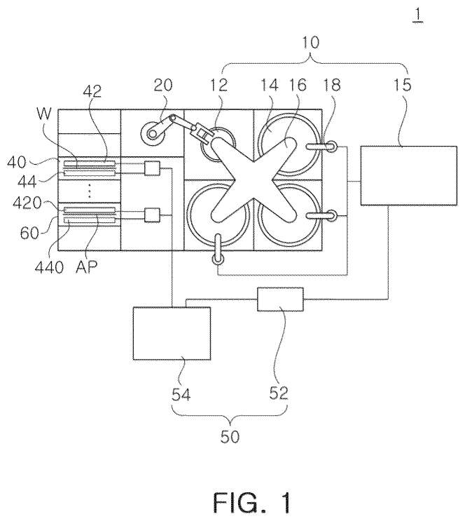

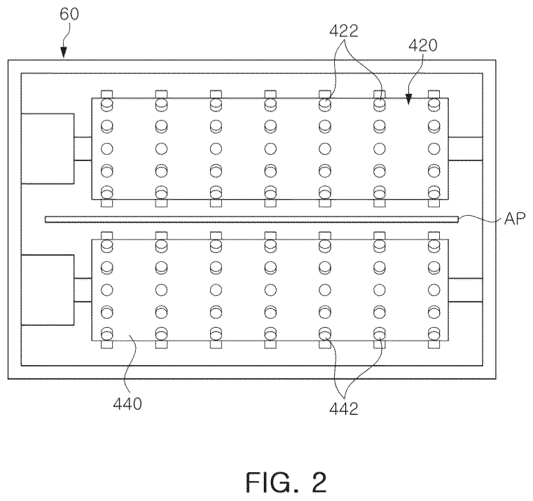

FIG. 1 is a schematic diagram of a chemical mechanical polishing apparatus for a semiconductor wafer according to one or more embodiments. FIG. 2 is a schematic diagram of a structure of a wafer surface cleaning apparatus of the chemical mechanical polishing apparatus of FIG. 1.

Referring to FIGS. 1 and 2, the chemical mechanical polishing apparatus 1 for a semiconductor wafer may include a polishing chamber 10, a wafer cleaning chamber 40, and a brush aging chamber 60.

The polishing chamber 10 may include a polishing module that may polish a surface of a wafer W. The polishing module may include, for example, a load cup 12, a polishing pad 14, a polishing head 16, a slurry nozzle 18, and a slurry supply unit 15.

The load cup 12 may be disposed to be adjacent to a robot arm 20, and the robot arm 20 may move the polished wafer W, positioned on the load cup 12, to the wafer cleaning chamber 40.

The polishing pad 14 may be disposed to be adjacent to the load cup 12, and may polish the wafer W. The polishing pad 14 may include, for example, non-woven fabric. The wafer W may be sequentially provided on a plurality of polishing pads 14.

The polishing head 16 may transfer the wafer W between the polishing pad 14 and the load cup 31. For example, the polishing head 16 may vacuum-adsorb the wafer W and transfer the wafer W between the polishing pad 14 and the load cup 31. In addition, the polishing head 16 may rotate the wafer W on the polishing pad 14, and the wafer W and the polishing pad 14 may be polished by friction.

The slurry nozzle 18 may be disposed on a portion of the polishing pad 14, and may be connected to the slurry supply unit 15. A slurry may assist in or accelerate polishing of the wafer W, and may include an abrasive dispersed in a solution polishing a dielectric thin film such as silicon oxide or silicon nitride or a metal thin film such as copper. The abrasive to polish the dielectric thin film may include silica or ceria, and the abrasive to polish the metal thin film may include hydrogen peroxide or aqueous ammonia.

In the wafer cleaning chamber 40, the polished wafer W, moved by the robot arm 20, may be cleaned. In the wafer cleaning chamber 40, as illustrated in FIG. 2, a slurry on the polished wafer W may be cleaned using rinsing or an etchant. In addition, the wafer W may be disposed between a pair of brushes 42 and 44 and be brushed by the brushes 42 and 44.

The wafer cleaning chamber 40 may perform a function the same as a function of the brush aging chamber 60. In the same manner as the wafer cleaning chamber 40, the brush aging chamber 60 may accommodate a pair of brushes 420 and 440.

The brush aging pad AP may be disposed between the pair of brushes 420 and 440 in the brush aging chamber 60, and may age surface protrusions 422 and 442 of the brushes 420 and 440.

The brush aging pad AP may be inserted into or removed from the brush aging chamber 60 by a transfer apparatus transferring the wafer 20 to be cleaned in the brush aging chamber 60. The transfer apparatus may be the robot arm 20 of the chemical mechanical polishing apparatus 1. An entrance through which the brush aging pad AP is inserted into or removed from the brush aging chamber 60 may be formed in the brush aging chamber 60.

The brush aging pad AP may be inserted into the brush aging chamber 60 to age the surface protrusions 422 and 442 of the brushes 420 and 440, and may then be removed from the brush aging chamber 60, and the polished wafer W may be inserted into the brush aging chamber 60 and cleaned in the same manner as the wafer cleaning chamber 40.

The brush aging pad AP may have a shape of the wafer W having a surface having a surface roughness, and may be inserted into and removed from the brush aging chamber 60 in the same manner as the wafer W, and a detailed description thereof will be provided below.

A control unit 50 of the chemical mechanical polishing apparatus 1 according to the example embodiment of FIG. 1 may control the polishing chamber 10, the wafer cleaning chamber 40, and the brush aging chamber 60. The polishing control unit 52 may also control opening and closing of the slurry nozzle 18. When a plurality of slurries are used, a slurry may be selected, and an amount thereof may be adjusted.

In addition, a cleaning control unit 54 may be connected to the wafer cleaning chamber 40 and the brush airing chamber 60 to control rinsing, use of an etchant, brushing, aging, or the like.

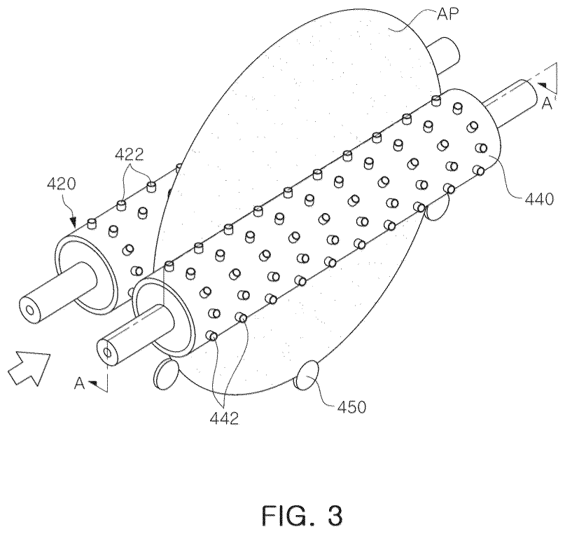

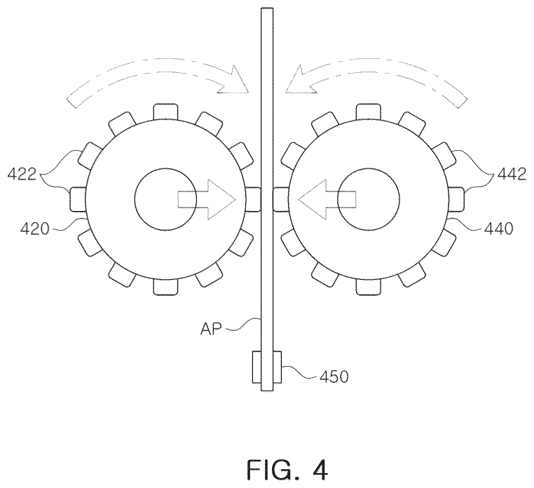

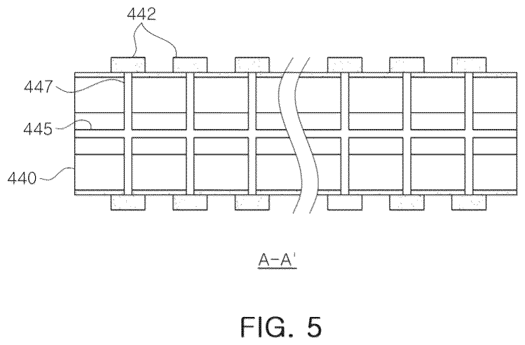

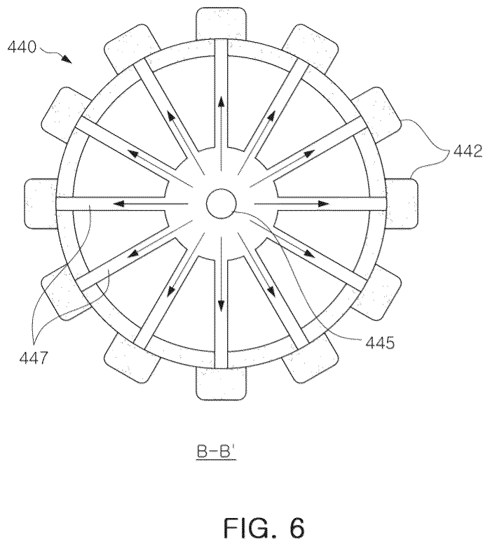

FIG. 3 is a schematic perspective view of a brush and an aging pad according to one or more embodiments. FIG. 4 is a schematic side view in a direction of the arrow of FIG. 3. FIG. 5 is a schematic cross-sectional view of a brush taken along line A-A′ of FIG. 3. FIG. 6 is a schematic cross-sectional view of a brush taken along line B-B′ of FIG. 5.

Referring to FIGS. 3 to 6, a target to be aged by an aging pad AP in a brush aging chamber 60 may be surface protrusions 422 and 442 of brushes 420 and 440 that are not aged.

The brush aging chamber 60 may further include a jig 450 supporting the brush aging pad AP to rotate.

A film may be formed on the surface protrusions 422 and 442 of the brushes 420 and 440 that are not aged. The pair of brushes 420 and 440 may be positioned such that the surface protrusions 422 and 442 of the brushes are in contact with the aging pad AP to press the aging pad AP, as illustrated in FIGS. 3 and 4.

The pair of brushes 420 and 440 may be rotated in a pressing direction in a state in which the surface protrusions 422 and 442 of the brushes are in contact with the aging pad AP to press the aging pad AP, and the brush aging pad AP may also be rotated by the jig 450. The brush surface protrusions 422 and 442 may be scrubbed by such pressure and rotation.

Referring to FIGS. 5 and 6, a movement path of deionized water (DIW) may be seen in a cross-section of the brush 440.

A central deionized water flow path 445 may be formed at the center of the brush 440, and a branch deionized water flow path 447, branching from the central deionized water flow path 445 toward the surface protrusion 442 of the brush 440, may be formed.

A material of a surface of the brush 440 may include, for example, polyvinyl alcohol (PVA). polyvinyl alcohol, a colorless, odorless solid, may have relatively high film-forming, emulsion, and adhesive properties, but may be a water-soluble polymer.

When deionized water is transferred to the surface protrusion 442 of the brush 440, the deionized water may pass through the surface protrusion 422, and may flow out through pores generated by the properties of the material of the surface protrusion 442 of the brush 440.

A surface roughness (Ra) of the surface protrusion 442 of the brush 440 that is in an initial state may be about 60 μm to 70 μm. When the wafer W, polished to be in an initial state thereof, is cleaned without aging the surface protrusion 442 of the brush 440, a significant number of particles of tens of nanometers may be present.

In order to remove particles, aging may be performed by scrubbing the surface protrusions 422 and 442 of the brushes in a state in which the surface protrusions 422 and 442 of the brushes are in contact with the aging pad AP to press the aging pad AP. Aging may be performed by rotating the brushes 420 and 440 and the aging pad AP and supplying deionized water, such that the surface roughness (Ra) of the surface protrusion 442 of the brush 440 may be between 40 μm and 50 μm.

As described, when the polished wafer W is cleaned using the surface protrusion 442 of the brush 440 that is in an aged state, particles of tens of nanometers, present on a surface of the wafer W, may be cleaned, thereby reducing particle contamination.

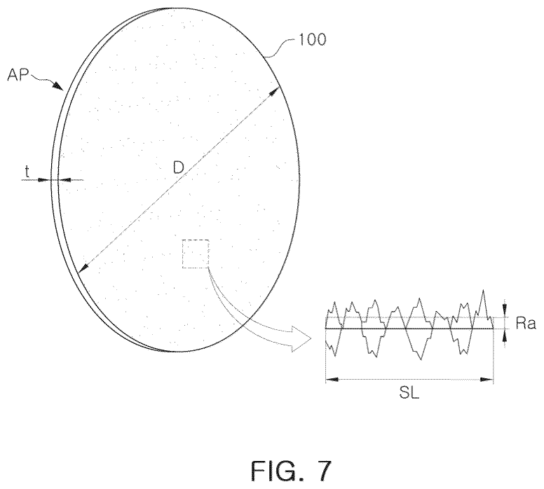

FIG. 7 is a schematic perspective view of aging of a brush using an aging pad according to one or more embodiments.

Referring to FIG. 7, a brush aging pad AP may be a pad aging surface protrusions 422 and 442 of brushes 420 and 440 cleaning a semiconductor wafer W in the chemical mechanical polishing cleaning apparatus 1 described above with reference to FIGS. 1 to 6.

At least one surface of a pad body 100 of the brush aging pad AP may have a surface roughness Ra of 1 to 5 μm.

The surface roughness Ra, a parameter representing a surface roughness of the pad body 100, may refer to an arithmetic average roughness. A surface roughness for a sampling length (SL) in a specific sampling region randomly extracted from a surface of the pad body 100 may form a fine surface roughness of 1 μm to 5 μm. When the surface roughness Ra is greater than 5 μm, the wafer W, a target to be cleaned, may be broken. When the surface roughness Ra is less than 1 μm, processing may be difficult due to processing errors.

A material of the pad body 100, having a hardness greater than a hardness of the wafer W, may be selected, and may include, for example, one of quartz, plastic, metal, and silicon.

In addition, the pad body 100, an apparatus for transferring the wafer W, may have a wafer shape to enable transfer, and may have a thickness (t) less than or equal to 1 mm. The wafer shape may be a circular shape in a cross-sectional direction. In addition, the pad body 100 may have a diameter (D) of 200 mm or 300 mm in the same manner as a diameter of a general wafer.

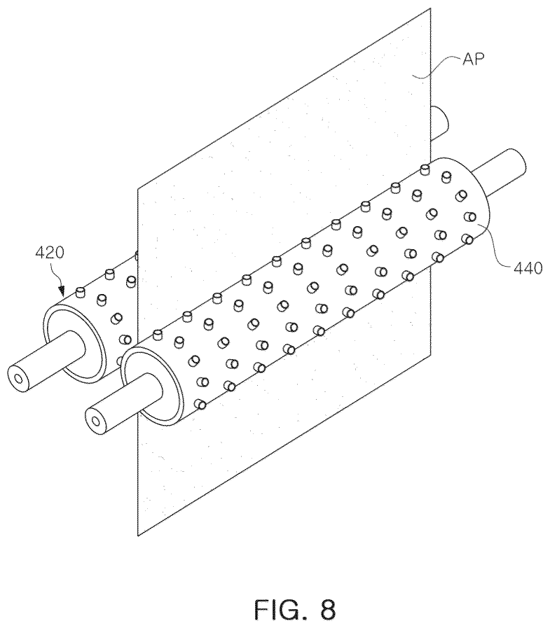

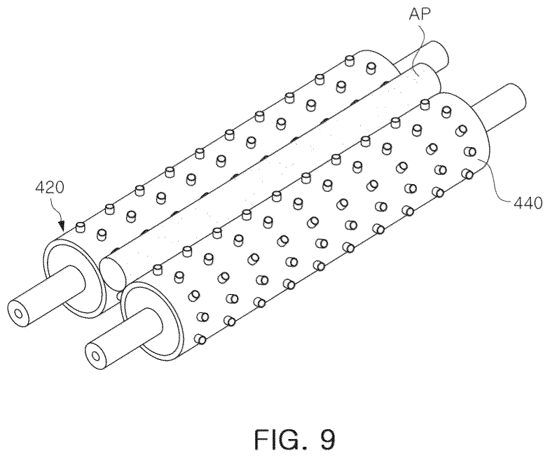

FIG. 8 is a schematic perspective view of aging of a brush using an aging pad according to one or more other embodiments. FIG. 9 is a schematic perspective view of aging of a brush using an aging pad according to one or more other embodiments.

Referring to FIGS. 8 and 9, a brush aging pad AP may have, for example, a square plate shape or a cylindrical shape according to one or more other embodiments.

The shape of the brush aging pad AP is not particularly limited, and the brush aging pad AP may be manufactured by performing artificial sanding or sandblasting such that a surface of the pad has a fine surface roughness of 1 μm to 5 μm.

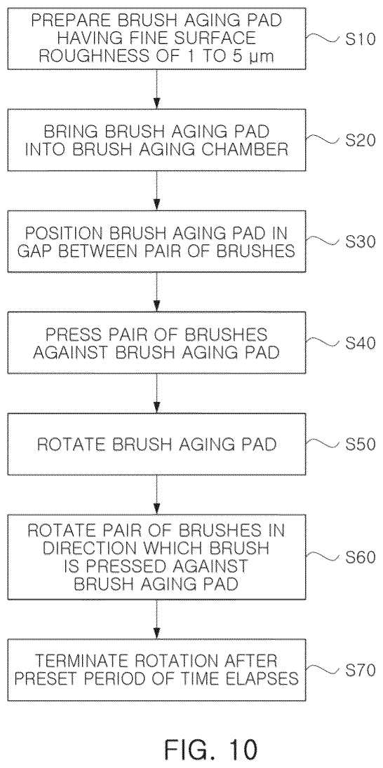

FIG. 10 is a flowchart of a brush aging method according to one or more embodiments.

FIG. 10 illustrates sequential operations of a method of aging surface protrusions 422 and 442 of brushes 420 and 440 using a brush aging pad AP according to according to one or more embodiments.

In operation S10, a brush aging pad AP having a fine surface roughness (Ra) of 1 μm to 5 μm may be prepared. In operation S20, the brush aging pad AP may be inserted into a brush aging chamber 60. In operation S30, the brush aging pad AP may be disposed in a gap between a pair of brushes 420 and 440 in the brush aging chamber 60.

Here, a surface roughness (Ra) of the surface protrusions 422 and 442 of the brushes 420 and 440 that are in an initial state may be about 60 μm to 70 μm. When the wafer W is cleaned using the brushes 420 and 440 having the surface protrusions 422 and 442 having the above-described surface roughness (Ra) without aging, particle contamination may be present.

In operation S40, the pair of brushes 420 and 440 may be pressed against the brush aging pad AP, such that the surface protrusions of the brushes may be inserted into contact with the brush aging pad AP.

In operation S50, the brush aging pad AP may be rotated, and in operation S60, the pair of brushes 420 and 440 may be rotated in a direction in which the brushes 420 and 440 are pressed against the brush aging pad AP.

The rotation of the brush aging pad AP (S50) and the rotation of the brushes 420 and 440 (S60) may be exchanged in terms of order, and may be simultaneously performed.

In operation S70, the rotation of the brush aging pad AP (S50) and the rotation of the brushes 420 and 440 (S60) may be terminated after a preset period of time elapses. The preset period of time may be a period of time randomly selected between 40 minutes and 70 minutes.

When the above-described preset period of time elapses in operation S70, the surface roughness (Ra) of the surface protrusions 422 and 442 of the brushes 420 and 440 may be between 40 μm and 50 μm.

Table 1 shows examples of aging according to one or more embodiments.

TABLE 1

| | | | | | Pressure rate | |
|---|---|---|---|---|---|---|
| | | Internal | | Rotation | of protrusion | |
| | Spraying of | flow of | Rotation | of aging | and aging pad | |
| Parameter/ | deionized | deionized | of brush | pad | (overlapping, | Process |
| Aging step | water (ml) | water (ml) | (RPM) | (RPM) | mm) | time (min) |
| Aging | 1500~2000 | off | 200~500 | 20~50 | −1~3 | 10 |
| Rinsing | 1500~2000 | 1500~2000 | 200~500 | 20~50 | −1~3 | 1 |
| Aging | 1500~2000 | off | 200~500 | 20~50 | −1~3 | 10 |
| Rinsing | 1500~2000 | 1500~2000 | 200~500 | 20~50 | −1~3 | 1 |

When aging and rinsing sets are repeatedly performed four to six times under the same conditions as those indicated in Table 1, the surface roughness (Ra) of the surface protrusions 422 and 442 of the brushes 420 and 440 may be between 40 μm and 50 μm.

As described, aging may be performed by scrubbing the surface protrusions 422 and 442 of the brushes in a state in which the surface protrusions 422 and 442 of the brushes are in contact with the aging pad AP to press the aging pad AP. Aging and rinsing may be performed by rotating the brushes 420 and 440 and the aging pad AP and supplying deionized water, such that the surface roughness (Ra) of the surface protrusion 442 of the brush 440 may be between 40 μm to 50 μm.

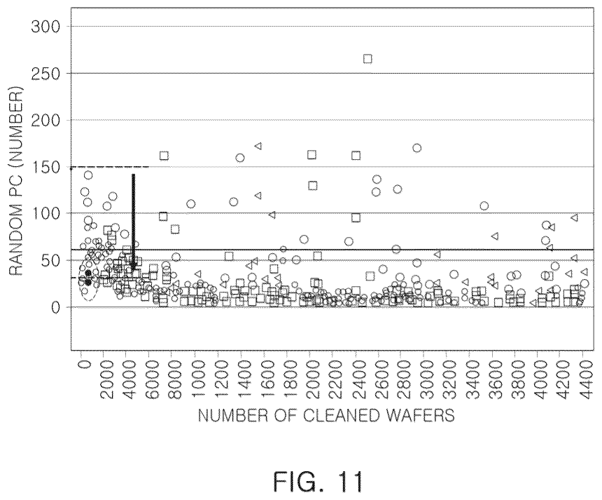

FIG. 11 is data of results of comparing particle contamination of wafer cleaning after brush aging is performed using a brush aging method according to one or more embodiments with particle contamination according to the related art.

In FIG. 11, a vertical axis may represent the number of particles found on a randomly selected wafer after being cleaned using a brush, and a horizontal axis may represent the number of wafers cleaned using a single brush.

Those indicated by shapes, such as triangles, squares, and circles, indicated by indistinct blank spaces may be data obtained by randomly selecting a wafer cleaned using a brush that is not aged and examining the number of particles on the wafer.

Until about 5,000 wafers are cleaned using a single brush indicated by an arrow, a large number of particles, up to 150, may be present on a randomly selected wafer.

For example, when a wafer is cleaned using a brush that is in an initial, unaged state, for example, the brush having a surface protrusion having a surface roughness (Ra) of about 60 μm to 70 μm, it may be defined that there is particle contamination.

However, when the polished wafer W is cleaned using a surface protrusion 442 of a brush 440 that is in an aged state, for example, the brush 440 having the surface protrusion 442 having a surface roughness (Ra) of 40 μm to 50 μm, about 25 particles of tens of nanometers may be found to be present on a surface of the wafer W, as indicated by circular dots having filled blank spaces.

Wafer cleaning power, increasing due to a reduction in the number of particles from about 150 to about 25, may be confirmed.

According to a brush aging pad, a chemical mechanical polishing apparatus, and a brush aging method according to one or more embodiments, immediately after replacement with a new brush, a surface protrusion of the brush may be aged, and then a wafer may be cleaned, thereby improving particle contamination of the initially cleaned wafer even when the new brush is used.

In addition, aging may be performed using a brush aging pad in a brush aging chamber, thereby reducing wafer cleaning time.

In addition, particle contamination of a wafer may be reduced, thereby increasing wafer production volume.

While embodiments have been shown and described above, it will be apparent to those skilled in the art that modifications and variations could be made without departing from the scope of the present inventive concept as defined by the appended claims and their equivalents.

1. A brush aging pad configured to age a surface protrusion of a brush configured to clean a semiconductor wafer in a chemical mechanical polishing cleaning apparatus, the brush aging pad comprising:
a pad body,
wherein a surface roughness of at least one surface of the pad body ranges from 1 μm to 5 μm.

2. The brush aging pad of claim 1, wherein a material of the pad body comprises one of quartz, plastic, metal, and silicon.

3. The brush aging pad of claim 1, wherein the pad body has a circular shape, and
wherein a thickness of the pad body is less than or equal to 1 mm.

4. The brush aging pad of claim 3, wherein the circular shape has a diameter of 200 mm or 300 mm.

5. The brush aging pad of claim 1, wherein the pad body has a plate shape or a cylindrical shape.

6. A chemical mechanical polishing apparatus comprising:
a brush aging chamber configured to accommodate a pair of brushes; and
a brush aging pad between the pair of brushes included in the brush aging chamber, the brush aging pad configured to age a surface protrusion of the brush,
wherein the brush aging pad comprises a pad body, a surface roughness of at least one surface of the pad body ranging from 1 μm to 5 μm.

7. The chemical mechanical polishing apparatus of claim 6, wherein the brush aging pad is inserted into or removed from the brush aging chamber by a transfer apparatus configured to transfer a wafer to be cleaned in the brush aging chamber.

8. The chemical mechanical polishing apparatus of claim 6, wherein the brush aging chamber further comprises a jig supporting the brush aging pad, and
wherein the pair of brushes are configured such that a surface protrusion of each of the pair of brushes is in contact with the brush aging pad and configured to press the brush aging pad.

9. The chemical mechanical polishing apparatus of claim 6, wherein a deionized water flow path is included in the brush, and
wherein deionized water, configured to flow in the deionized water flow path, flows out through the surface protrusion of each of the pair of brushes.

10. The chemical mechanical polishing apparatus of claim 6, wherein a material of the pad body comprises one of quartz, plastic, metal, and silicon.

11. The chemical mechanical polishing apparatus of claim 6, wherein the pad body has a circular shape, and
wherein a thickness of the pad body is less than or equal to 1 mm.

12. The chemical mechanical polishing apparatus of claim 6, wherein the circular shape has a diameter of 200 mm or 300 mm.

13. The chemical mechanical polishing apparatus of claim 6, wherein the pad body has a plate shape or a cylindrical shape.

14. A chemical mechanical polishing apparatus comprising:
a brush aging chamber configured to accommodate a brush; and
a brush aging pad configured to be in contact with and to be pressed against a surface protrusion of the brush included in the brush aging chamber,
wherein the brush aging pad comprises a pad body having circular shape, a surface roughness of at least one surface of the pad body ranging from 1 μm to 5 μm.

15. The chemical mechanical polishing apparatus of claim 14, wherein a material of the pad body comprises one of quartz, plastic, metal, and silicon.

16. The chemical mechanical polishing apparatus of claim 14, wherein a thickness of the pad body is less than or equal to 1 mm.

17. The chemical mechanical polishing apparatus of claim 14, wherein the circular shape has a diameter of 200 mm or 300 mm.

18. The chemical mechanical polishing apparatus of claim 14, wherein the brush aging pad is inserted into or removed from the brush aging chamber by a transfer apparatus configured to transfer a wafer to be cleaned in the brush aging chamber.

19. The chemical mechanical polishing apparatus of claim 14, wherein the brush aging chamber further comprises a jig supporting the brush aging pad.

20. The chemical mechanical polishing apparatus of claim 14, wherein a deionized water flow path is included in the brush, and
wherein deionized water, configured to flow in the deionized water flow path, flows out through the surface protrusion of the brush.

21-27. (canceled)
